(19) United States
(12) Patent Application Publication
(10) Pub. No.: US 2025/0151464 A1
(43) Pub. Date: May 8, 2025

(54) LIGHT EMITTING DIODE AND LIGHT EMITTING DEVICE

(71) Applicant: XIAMEN SAN'AN OPTOELECTRONICS CO., LTD., Xiamen (CN)

(72) Inventors: XIUSHAN ZHU, Xiamen (CN); YAN LI, Xiamen (CN); QI JING, Xiamen (CN); Zhihao BAO, Xiamen (CN); Qingchao YANG, Xiamen (CN); Chunhsien LEE, Xiamen (CN); Chi-Ming TSAI, Xiamen (CN); Juchin TU, Xiamen (CN); Chung-Ying CHANG, Xiamen (CN)

(21) Appl. No.: 18/938,219

(22) Filed: Nov. 5, 2024

(30) Foreign Application Priority Data
Nov. 7, 2023 (CN) 2023114752455

(51) Int. Cl. H01L 33/10; H01L 25/075; H01L 33/38

(52) U.S. Cl. CPC H10H 20/814; H10H 20/8314; H10H 20/8316; H01L 25/0753

(57) ABSTRACT

An LED and a light emitting device are provided, which includes an epitaxial structure, a transparent conductive layer, an insulating structure and a metal reflective layer. The epitaxial structure includes a first semiconductor layer, an active layer and a second semiconductor layer. The transparent conductive layer is disposed on the second semiconductor layer. The insulating structure is disposed on the transparent conductive layer, and an opening is defined in the insulating structure. The transparent conductive layer is exposed from the opening. A step portion is formed on a sidewall of the opening, and divides the opening into a first opening and a second opening. An opening width of the first opening is smaller than that of the second opening. The metal reflective layer is disposed on the insulating structure. The metal reflective layer fills the first opening and the second opening, and forms electrical contact with the second semiconductor layer.

### CROSS-REFERENCE TO RELATED APPLICATION

This application claims priority to Chinese Patent Application No. 202311475245.5, filed on Nov. 7, 2023, which is herein incorporated by reference in its entirety.

### TECHNICAL FIELD

The present disclosure relates to the technical field of semiconductor devices, and particularly to a light emitting diode (LED) and a light emitting device.

### BACKGROUND

An LED is a solid-state light-emitting device that converts electric energy into light energy. Because of its advantages of longer life, smaller volume, good shock resistance, power saving, high efficiency, faster response time, lower driving voltage and environmental protection, the LED is widely used in many fields such as indication, display, decoration and lighting.

At present, it is difficult to improve an external quantum efficiency of the LED. For example, light emitted from an epitaxial layer of the LED is easily absorbed by a metal electrode disposed above the epitaxial layer, thereby reducing a light-emitting efficiency of the LED. In the related art, a reflective layer is usually disposed between the metal electrode and the epitaxial layer to improve the light-emitting efficiency of the LED. However, a reflective efficiency of the reflective layer is very limited, therefore, how to further improve the light-emitting efficiency of the LED has become an urgent problem in this field.

### SUMMARY

In view of the shortcomings of the related art mentioned above, an objective of the present disclosure is to provide an LED and a light emitting device to improve the light-emitting efficiency of the LED.

In order to achieve the above objective and other related objectives, in one aspect, an embodiment of the present disclosure provides an LED, which includes:
an epitaxial structure, including a first semiconductor layer, an active layer and a second semiconductor layer, which are sequentially stacked in that order;
a transparent conductive layer, disposed on a side of the second semiconductor layer facing away from the active layer;
an insulating structure, where the insulating structure is disposed on a side of the transparent conductive layer facing away from the epitaxial structure, the insulating structure is defined with an opening, the transparent conductive layer is exposed from the opening, a step portion is formed on a sidewall of the opening, the opening is divided by the step portion into a first opening and a second opening, the first opening is closer to the transparent conductive layer compared with the second opening, and an opening width of the first opening is smaller than an opening width of the second opening; and a metal reflective layer, where the metal reflective layer is disposed on a side of the insulating structure facing away from the transparent conductive layer, the first opening and the second opening are filled with the meal reflective layer, and the metal reflective layer is electrically in contact with the second semiconductor layer through the transparent conductive layer.

In another aspect, an embodiment of the present disclosure provides a light emitting device, which includes:
a package substrate; and
at least one LED, disposed on a surface of the package substrate, the package substrate is electrically connected to the at least one LED, and each of the at least one LED is the LED described above.

Compared with the related art, the LED and the light emitting device have at least the following beneficial effects.

The LED in the present disclosure includes an epitaxial structure, a transparent conductive layer, an insulating structure and a metal reflective layer. Specifically, the epitaxial structure includes a first semiconductor layer, an active layer and a second semiconductor layer which are sequentially stacked in that order. The transparent conductive layer is disposed on the second semiconductor layer. The insulating structure is disposed on the transparent conductive layer, and an opening is defined in the insulating structure. The transparent conductive layer is exposed from the opening. A step portion is formed on a sidewall of the opening, and the step portion divides the opening into a first opening and a second opening. The first opening is closer to the transparent conductive layer compared with the second opening. An opening width of the first opening is smaller than that of the second opening. The metal reflective layer is disposed on the insulating structure. The metal reflective layer fills the first opening and the second opening, and forms electrical contact with the second semiconductor layer through the transparent conductive layer. In the present disclosure, the opening is formed with the step portion, the step portion divides the opening into the first opening and the second opening, and the opening width of the first opening is smaller than that of the second opening, so that an contact area between the metal reflective layer and the insulating structure can be increased, an reflection efficiency of the metal reflective layer can be increased, and a light-emitting efficiency of the LED can be further improved.

The light emitting device of the present disclosure includes the LED, and also has the above technical effects.

### BRIEF DESCRIPTION OF DRAWINGS

FIG. 1 illustrates a schematic sectional view of an LED according to an embodiment 1 of the present disclosure.

FIG. 2 illustrates an enlarged view of a portion at a position A in FIG. 1.

FIG. 3 illustrates a schematic sectional view of an LED according to an embodiment 2 of the present disclosure.

FIG. 4 illustrates an enlarged view of a portion at a position A in FIG. 3.

FIG. 5 illustrates another enlarged view of a portion at a position A in FIG. 3.

FIG. 6 illustrates a schematic structural view of an insulating reflective layer 402 in FIG. 3 according to an embodiment of the present disclosure.

FIG. 7 illustrates a schematic structural diagram of a second semiconductor layer after a transparent conductive layer, a first insulating layer and an insulating reflective layer are sequentially formed on a surface of the second semiconductor layer in an embodiment of the present disclosure.

FIG. 8 illustrates a schematic structural view of a corresponding structure of FIG. 6 after a second opening is defined in the insulating reflective layer.

FIG. 9 illustrates a schematic structural view of a corresponding structure of FIG. 7 after a first opening is defined in the first insulating layer.

FIG. 10 illustrates a structural schematic diagram of a light emitting device according to an embodiment of the present disclosure.

### REFERENCE NUMERALS

100 Substrate
200 Epitaxial structure
201 First semiconductor layer
202 Active layer
203 Second semiconductor layer
204 Through hole
300 Transparent conductive layer
400 Insulating structure
401 First insulating layer
4011 First opening
4013 Third opening
402 Insulating reflective layer
4021 Second opening
4023 First material layer
4024 Second material layer
500 Step portion
600 Metal reflective layer
701 First electrode contact layer
702 Second electrode contact layer
801 First electrode
802 Second electrode
900 Second insulating layer
1000 Protective layer
001 Package substrate
002 LED

### DETAILED DESCRIPTION OF EMBODIMENTS

In order to improve a light-emitting efficiency of an LED, the present disclosure an LED, which includes an epitaxial structure, a transparent conductive layer, an insulating structure and a metal reflective layer. Specifically, the epitaxial structure includes a first semiconductor layer, an active layer and a second semiconductor layer which are sequentially stacked in that order. The transparent conductive layer is disposed on the second semiconductor layer. The insulating structure is disposed on the transparent conductive layer, and an opening is defined in the insulating structure. The transparent conductive layer is exposed from the opening. A step portion is formed on a sidewall of the opening, and the step portion divides the opening into a first opening and a second opening. The first opening is closer to the transparent conductive layer compared with the second opening. An opening width of the first opening is smaller than that of the second opening. The metal reflective layer is disposed on the insulating structure. The metal reflective layer fills the first opening and the second opening, and forms electrical contact with the second semiconductor layer through the transparent conductive layer. Therefore, the LED of the present disclosure has an omni-directional reflector (ODR) reflecting structure consisting of the insulating structure and the metal reflective layer above the epitaxial structure to reflect light emitted towards the ODR reflecting structure from the epitaxial structure. Further, an opening with a step portion is defined in the insulating structure, and the metal reflective layer is filled in the opening, so that a contact area between the metal reflective layer and the insulating structure is increased, a reflection efficiency of the metal reflective layer is increased, and a light-emitting efficiency of the LED is improved.

### Embodiment 1

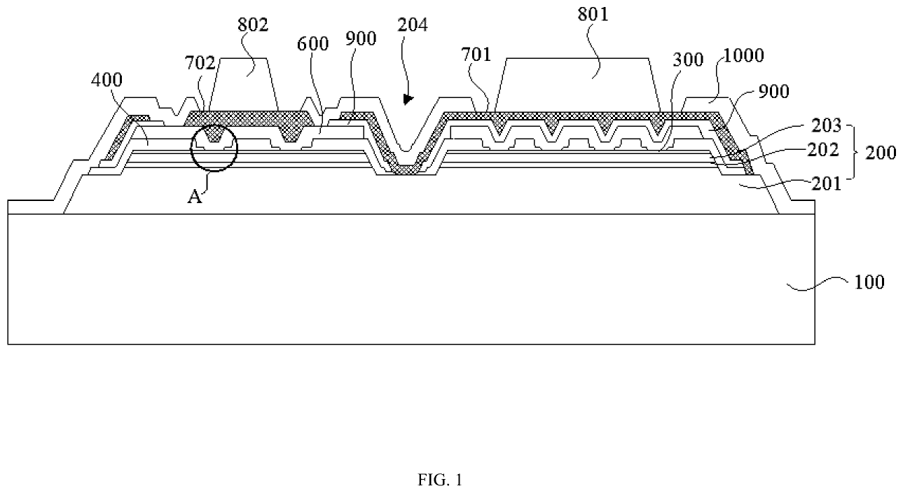

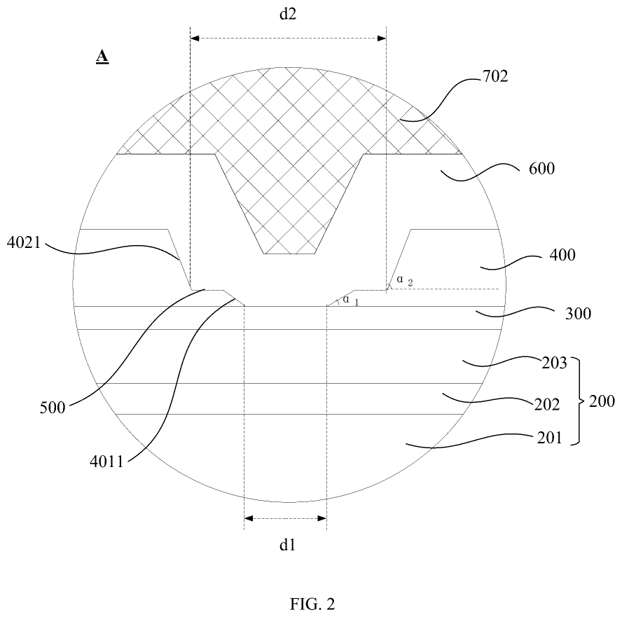

This embodiment provides an LED, as illustrated in FIGS. 1 and 2. The LED includes an epitaxial structure, a transparent conductive layer, an insulating structure and a metal reflective layer.

Specifically, as illustrated in FIG. 1, the LED includes a substrate 100, and an epitaxial structure 200 disposed on a surface of the substrate 100. The substrate 100 is a transparent substrate, which may be an insulating substrate or a conductive substrate. The transparent substrate may be a growth substrate for growing a light-emitting structure, and may include a sapphire substrate, a silicon carbide substrate, a silicon substrate, a gallium nitride substrate or an aluminum nitride substrate. The epitaxial structure 200 is formed on one surface of the substrate 100, and another surface of the substrate 100 opposite to the one surface is formed as a light emitting surface of the LED.

The epitaxial structure 200 is disposed on the surface of the substrate 100, and includes a first semiconductor layer 201, an active layer 202, and a second semiconductor layer 203 stacked in sequence from the surface of the substrate 100. The first semiconductor layer 201 may be an N-type semiconductor layer and the second semiconductor layer 203 may be a P-type semiconductor layer. Of course, the first semiconductor layer 201 may be a P-type semiconductor layer and the second semiconductor layer 203 may be an N-type semiconductor layer. The first semiconductor layer 201 is configured to provide electrons for composite luminescence, and the second semiconductor layer 203 is configured to provide holes for composite luminescence. The active layer 202 may be a single quantum well or a multi-quantum well, and is configured to perform composite luminescence of the electrons and the holes. Furthermore, the epitaxial structure 200 is defined with a through hole 204 etched from the second semiconductor layer 203 to the first semiconductor layer 201, a part of the first semiconductor layer 201 is exposed from a bottom of the through hole 204.

The transparent conductive layer 300 is disposed on the second semiconductor layer 203. The transparent conductive layer 300 mainly plays the role of ohmic contact and lateral current expansion. In this embodiment, the transparent conductive layer 300 is an ITO layer.

The insulating structure 400 is disposed on the transparent conductive layer 300. A material of the insulating structure 400 can be one or more of SiO₂, Si₃N₄, TiO₂, Ti₂O₃, Ti₃O₅, Ta₂O₅, and ZrO₂. In this embodiment, the insulating structure 400 is a silicon dioxide layer. Referring to FIG. 2, the insulating structure 400 is defined with an opening which exposes the transparent conductive layer 300. A step portion 500 is formed on a sidewall of the opening, and the step portion 500 divides the opening into a first opening 4011 and a second opening 4021. The first opening 4011 is closer to the transparent conductive layer 300 compared with the second opening 4021, and an opening width of the first opening 4011 is smaller than an opening width of the second opening 4021.

In an embodiment, referring to FIG. 2, the opening width of the first opening 4011 gradually increases in a direction from the transparent conductive layer 300 to the second opening 4021, and the opening width of the second opening 4021 gradually increases in a direction from the first opening 4011 to a metal reflective layer 600. In an embodiment, an inclination of a sidewall of the first opening 4011 is smaller than an inclination of a sidewall of the second opening 4021, that is to say, an included angle di between the sidewall of the first opening 4011 and a plane where the substrate 100 is located is smaller than an included angle α₂ between the sidewall of the second opening 4021 and the plane where the substrate 100 is located. In an embodiment, a value of α₁ is in a range from 10° to 30°, and a value of α₂ is in a range from 20° and 60°. The inclinations of the sidewalls of the first opening 4011 and the second opening 4012 are matched, so that a specific opening shape structure can be formed, more light can be reflected to the light emitting surface of the LED, and light loss in a light reflection path can be avoided.

In an embodiment, the sidewall of the first opening 4011 and the sidewall of the second opening 4021 may be formed in a straight-line shape or an arc shape. In this embodiment, referring to FIG. 2, the sidewall of the first opening 4011 is straight-line shaped, and the sidewall of the second opening 4021 is straight-line shaped.

In an embodiment, referring to FIG. 2, an opening width d2 of a lower opening of the second opening 4021 is twice larger than an opening width d1 of a lower opening of the first opening 4011, thereby increasing an area of the step portion between the first opening 4011 and the second opening 4012. The contact of the step portion with the metal reflective layer 600 can increase the reflection effect of the LED. It should be noted that the lower opening of the first opening 4011 in this embodiment refers to an edge opening of the first opening 4011 close to the transparent conductive layer 300, and the lower opening of the second opening 4021 in this embodiment refers to an edge opening of the second opening 4021 close to the transparent conductive layer 300. In an embodiment, the opening width of the first opening 4011 is in a range from 1 μm to 5 μm, and the opening width of the second opening 4021 is in a range from 2 μm to 10 μm.

Referring to FIG. 1, the metal reflective layer 600 is disposed on the insulating structure 400. The metal reflective layer 600 filling the first opening 4011 and the second opening 4021, and is electrically in contact with the second semiconductor layer 203 of the epitaxial structure 200 through the transparent conductive layer 300. The metal reflective layer 600 can reflect light. In this embodiment, the metal reflective layer 600 is made of silver, that is to say, the metal reflective layer 600 is a silver layer.

Referring to FIG. 1, a first electrode 801 is disposed on the metal reflective layer 600 and is electrically connected with the metal reflective layer 600. In an embodiment, a first electrode contact layer 701 is disposed between the metal reflective layer 600 and the first electrode 801. A second electrode 802 is disposed on the metal reflective layer 600. The second electrode 802 is insulated from and connected with the metal reflective layer 600, and electrically connected with a part of the first semiconductor layer 201 of the epitaxial structure 200 exposed from the through hole 204. In an embodiment, a second insulating layer 900 and a second electrode contact layer 702 are sequentially formed on the metal reflective layer 600. The second electrode contact layer 702 extends from a surface of the second insulating layer 900 into the through hole 204 defined in the epitaxial structure 200, and is electrically connected with the first semiconductor layer 201 exposed from the through hole 204. The second electrode 802 is disposed on the second electrode contact layer 702. A material of each of the first electrode contact layer 701 and the second electrode contact layer 702 may be one material such as Al, Ni, Ti, Pt, Cr, Au or an alloy of at least two of these materials. A material of each of the first electrode 801 and the second electrode 802 may be Au or an alloy of Au.

Referring to FIG. 1, a protective layer 1000 is disposed on the epitaxial structure 200, covering a layer structure above the epitaxial structure 200, while exposing the first electrode 801 and the second electrode 802. In an embodiment, the protective layer 1000 may be an insulating layer, and a material of the protective layer 1000 may be one or more of SiO₂, Si₃N₄, TiO₂, Ti₂O₃, Ti₃O₅, Ta₂O₅, and ZrO₂.

The LED of the present disclosure has an ODR reflecting structure consisting of the insulating structure 400 and the metal reflective layer 600 above the epitaxial structure 200 to reflect light emitted towards the ODR reflecting structure from the epitaxial structure 200. Further, the opening with the step portion 500 is defined in the insulating structure 400, and the metal reflective layer 600 is filled in the opening, so that a contact area between the metal reflective layer 600 and the insulating structure 400 is increased, a reflection efficiency of the metal reflective layer is increased, and a light-emitting efficiency of the LED is improved.

### Embodiment 2

This embodiment provides another LED. The commonalities between the LED of the second embodiment and the LED of the first embodiment will not be repeated herein, and only the differences will be described below.

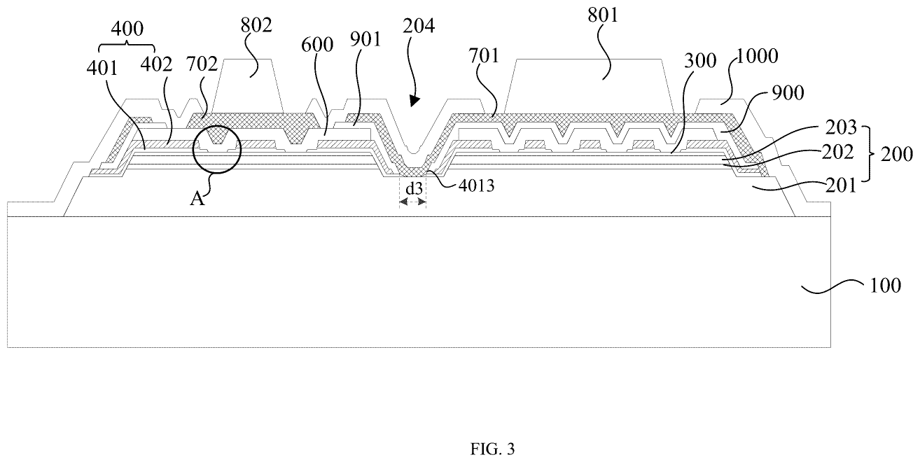

In this embodiment, referring to FIG. 3, the insulating structure 400 includes a first insulating layer 401 and an insulating reflective layer 402. The first insulating layer 401 is disposed on the transparent conductive layer 300, and the first opening 4011 is defined in a part of the first insulating layer 401 close to the transparent conductive layer 300. The insulating reflective layer 402 is disposed on the first insulating layer 401. The second opening 4021 is defined in the insulating reflective layer 402, and extends from the insulating reflective layer 402 to another part of the first insulating layer 401 and is in contact with an edge of the first opening 4011. Therefore, an ODR reflecting structure in this embodiment is composed of the first insulating layer 401, the insulating reflective layer 402 and the metal reflective layer 600. Due to the addition of the insulating reflective layer 402, the reflective efficiency of the ODR reflecting structure can be further improved, which contributes to the light-emitting efficiency of the light emitting diode.

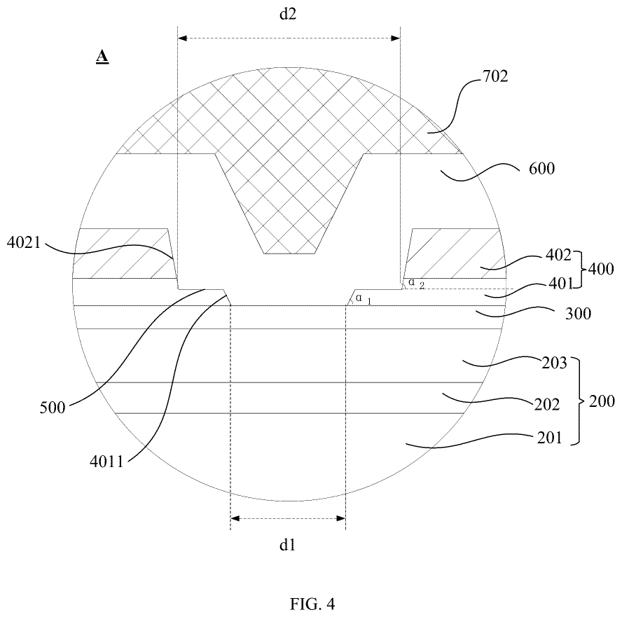

Referring to FIG. 4, the first insulating layer 401 is disposed above the transparent conductive layer 300 and below the insulating reflective layer 402. When the second opening 4021 is formed on the insulating reflective layer 402 by dry etching, the first insulating layer 401 can be used as an etching stop layer to avoid the etching of the transparent conductive layer 300 by the dry etching. A thickness of the first insulating layer 401 is limited to block dry etching. In an embodiment, a thickness of the insulating reflective layer 402 is greater than that of the first insulating layer 401. A material of the first insulating layer 401 may be one or more of SiO₂, Si₃N₄, TiO₂, Ti₂O₃, Ti₃O₅, or Ta₂O₅, ZrO₂. In this embodiment, the first insulating layer 401 is formed as a silicon dioxide layer.

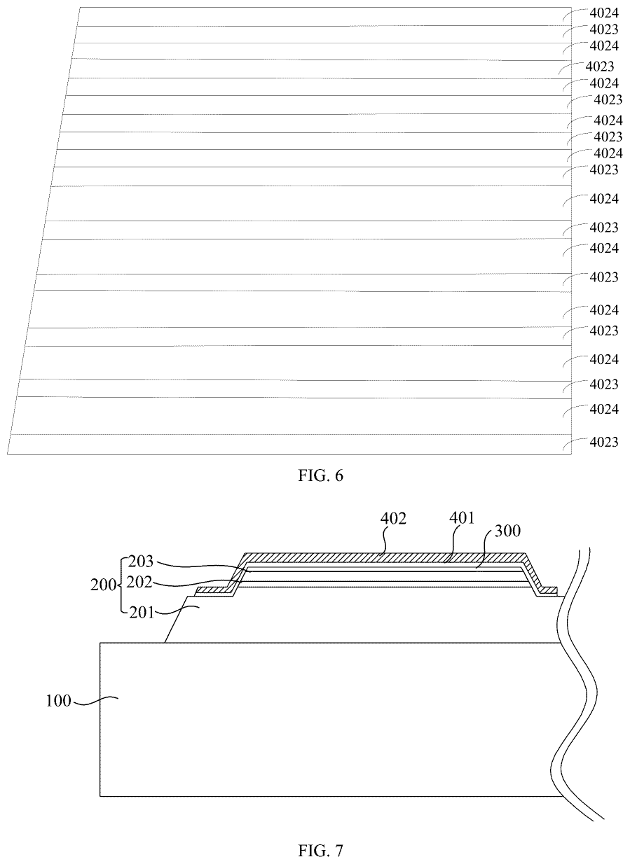

Referring to FIG. 4, the insulating reflective layer 402 is a distributed Bragg reflector (DBR) reflective layer. The DBR reflective layer is a Bragg reflective layer formed by alternately stacking materials with different refractive indices. A material of the Bragg reflection layer is at least two of different materials such as SiO₂, TiO₂, ZnO, ZrO₂ and Cu₂O₃. Specifically, the DBR reflective layer may be formed by alternately stacking a material of a higher refractive index and a material of a lower refractive index. In this embodiment, as illustrated in FIG. 6, the DBR reflective layer includes multiple layer pairs arranged in a stacked manner along a direction from the first insulating layer 401 to the insulating reflective layer 402. Each layer pair of the multiple layer pairs consists of a first material layer 4023 and a second material layer 4024, and a refractive index of the first material layer 4023 is greater than a refractive index of the second material layer 4024. That is, the second material layer 4024 is a lower refractive index layer, and the second material layer is a silicon oxide layer in this embodiment. The first material layer is a higher refractive index layer, and the first material layer is a titanium oxide layer in this embodiment.

In order to further improve the reflection efficiency of the ODR reflecting structure and the brightness of the LED, a thickness of the second material layer 4024 of at least one layer pair in half of the layer pairs close to the first insulating layer 401 of the DBR reflecting layer 402 is greater than a thickness of the second material layer 4024 of each layer pair in the other half of the layer pairs, which is more conducive to brightness enhancement of the LED.

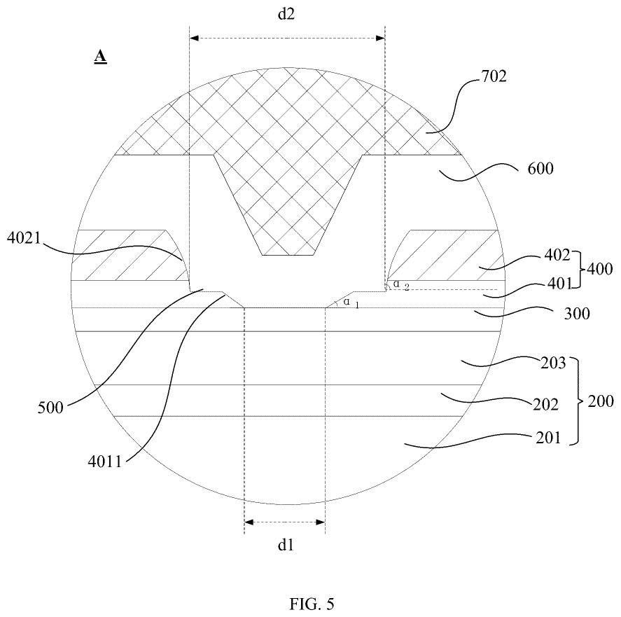

In an embodiment, referring to FIG. 4, a sidewall of the first opening 4011 is linear, and a sidewall of the second opening 4021 is also linear. In other embodiments, referring to FIG. 5, the sidewall of the first opening 4011 is linear, and the sidewall of the second opening 4021 is arc. The arc-shaped sidewall can further increase the contact area between the metal reflective layer 600 and the insulating structure 400, and increase the brightening effect. In an embodiment, referring to FIG. 5, the opening width of the first opening 4011 gradually increases in a direction from the transparent conductive layer 300 to the second opening 4021, and the opening width of the second opening 4021 gradually increases in a direction from the first opening 4011 to the metal reflective layer 600. An inclination of the sidewall of the first opening 4011 is greater than an inclination of the sidewall of the second opening 4021, that is to say, an included angle α₁ between the sidewall of the first opening 4011 and a plane where the substrate 100 is located is smaller than an included angle α₂ between the sidewall of the second opening 4021 and the plane where the substrate 100 is located. In an embodiment, a value of α₁ is in a range from 10° to 30°, and a value of α₂ is in a range from 20° and 60°. In this embodiment, the insulating structure 400 is matched with the inclinations and shapes of the sidewalls of the first opening 4011 and the second opening 4012, so that a specific opening shape structure can be formed, more light can be reflected to the light emitting surface of the LED, and light loss in a light reflection path can be avoided.

In order to avoid the influence of dry etching on the transparent conductive layer 300 when etching the second opening 4021, referring to FIGS. 6 to 8, a method for forming the insulating structure 400 includes the following steps.

Referring to FIG. 7, a substrate 100 is provided, and an epitaxial structure 200 is formed on a surface of the substrate 100. The epitaxial structure 200 sequentially includes a first semiconductor layer 201, an active layer 202 and a second semiconductor layer 203 from the surface of the substrate 100, and a part of the first semiconductor layer 201 of the epitaxial structure 200 is exposed. A transparent conductive layer 300, a first insulating layer 401 and an insulating reflective layer 402 are sequentially formed on the surface of the second semiconductor layer 203.

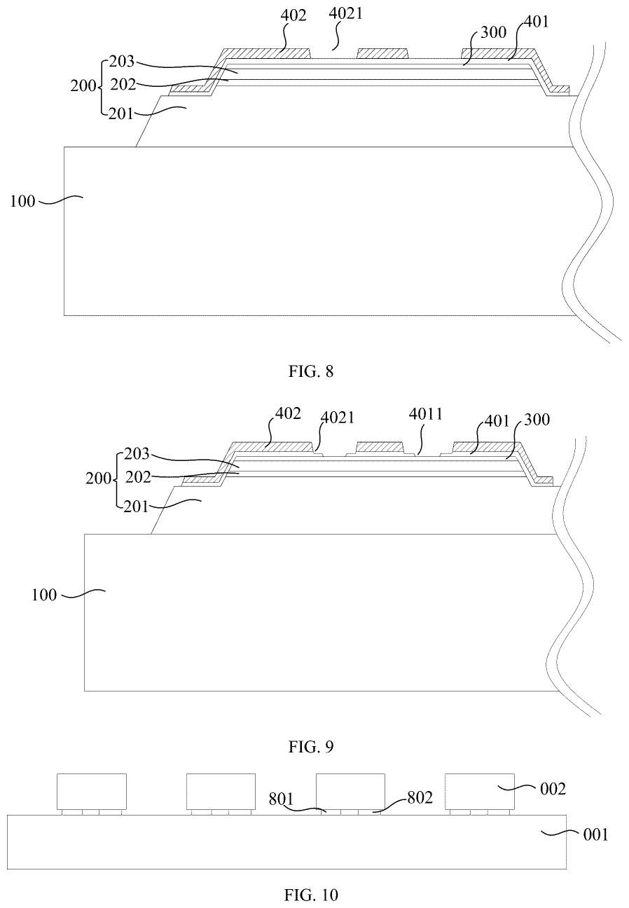

Referring to FIG. 8, a second opening 4021 is defined in the insulating reflective layer 402 by dry etching, and the second opening 4021 is formed by etching along a thickness direction of the insulating reflective layer 402 and penetrating through the insulating reflective layer 402 until a surface of the first insulating layer 401 is exposed. In this process, the first insulating layer 401 can be used as an etch stop layer for dry etching. Referring to FIG. 9, the first insulating layer 401 is etched along an opening position of the second opening 4021 by wet etching until the transparent conductive layer 300 is exposed to form the first opening 4011.

In this embodiment, the second opening 4021 on the DBR reflective layer 402 is formed first, and then the first opening 4011 is formed in the second opening 4021. Since the DBR reflective layer 402 is formed by dry etching, if the DBR reflective layer 402 is directly formed on the transparent conductive layer 300 and is dry etched to the transparent conductive layer 300, it will cause unnecessary etching damage to the transparent conductive layer 300. If it is not properly controlled, the transparent conductive layer 300 will even be etched through to the second semiconductor layer 203 below the transparent conductive layer 300, which will affect the reliability of the LED. In this embodiment, the first insulating layer 401 is formed on the transparent conductive layer 300, which can be used as an etching stop layer for dry etching. The second opening 4021 is formed in the DBR reflective layer 402, and the first insulating layer 401 below the DBR reflective layer 402 is etched by a wet etching process. During the wet etching process, the second opening 4021 extends downward into the first insulating layer 401, and the first opening 4011 is formed from the surface of the first insulating layer 401, to expose the transparent conductive layer 300. Since the wet etching process will not damage the transparent conductive layer 300, the formation method of this embodiment can protect the transparent conductive layer 300. Further, forming the ODR reflecting structure consisting of the first insulating layer 401, the DBR reflective layer 402 and metal reflective layer 600 above the epitaxial structure 200 will also increase the reflection effect of the light emitted by the epitaxial structure 200 and improve the light-emitting efficiency of the LED.

Referring to FIG. 3, a first opening is defined in the first insulating layer 401 at the through hole 204, a second opening is defined in the second insulating layer 402 at the through hole 204, and a third opening 4013 is defined in the second insulating layer 900 at the through hole 204. The opening width dl of the first opening 4011 is smaller than an opening width d3 of the third opening 4013, and the opening width d3 of the third opening 4013 is smaller than the opening width d2 of the second opening 4012. The first insulating layer 401 includes a first portion covering a sidewall of the through hole 204 and a second portion located on a surface of a part of the through hole 204. In an embodiment, the insulating reflective layer 402 is formed on the first portion and the second portion of the first insulating layer 401. If the insulating reflective layer 402 is only formed on the first portion of the first insulating layer 401, the first portion of the first insulating layer 401 may be damaged due to the dry etching of the insulating reflective layer 402, which may lead to electrical problems of the LED. In an embodiment, the insulating reflective layer 402 is not formed on the first portion and the second portion of the first insulating layer 401, but is only formed on the second semiconductor layer 203, which can avoid the problem that the reflectivity decreases due to the thicker second insulating layer 900 on the insulating reflective layer 402. In an embodiment, the opening width dl of the first opening 4011 is smaller than the opening width d2 of the second opening 4012, and the opening width d2 of the second opening 4012 is smaller than the opening width d3 of the third opening 4013.

### Embodiment 3

This embodiment provides a light emitting device. Referring to FIG. 10, the light emitting device includes a package substrate 001 and at least one LED 002 disposed on a surface of the package substrate 001. The package substrate 001 is electrically connected to electrodes 801 and 802 of each LED 002. Each of the at least one LED is the LED in the embodiment 1 or the embodiment 2. As mentioned above, since the LED in this embodiment is the LED in the embodiment 1 or the embodiment 2, the light emitting device has a good light emitting effect.

The above-mentioned embodiments merely illustrate the principle and efficacy of the present disclosure, and are not used to limit the present disclosure. Anyone familiar with this technology can modify or change the above embodiments without violating the spirit and scope of the present disclosure. Therefore, all equivalent modifications or changes made by people with ordinary knowledge in the technical field without departing from the spirit and technical ideas disclosed in the present disclosure should still be covered by the claims of the present disclosure.

What is claimed is:

1. A light emitting diode (LED), comprising:
an epitaxial structure, comprising a first semiconductor layer, an active layer and a second semiconductor layer, which are sequentially stacked in that order;
a transparent conductive layer, disposed on a side of the second semiconductor layer facing away from the active layer;
an insulating structure, wherein the insulating structure is disposed on a side of the transparent conductive layer facing away from the epitaxial structure, the insulating structure is defined with an opening, the transparent conductive layer is exposed from the opening, a step portion is formed on a sidewall of the opening, the opening is divided by the step portion into a first opening and a second opening, the first opening is closer to the transparent conductive layer compared with the second opening, and an opening width of the first opening is smaller than an opening width of the second opening; and
a metal reflective layer, wherein the metal reflective layer is disposed on a side of the insulating structure facing away from the transparent conductive layer, the first opening and the second opening are filled with the meal reflective layer, and the metal reflective layer is electrically in contact with the second semiconductor layer through the transparent conductive layer.

2. The LED as claimed in claim 1, wherein the opening width of the first opening gradually increases in a direction from the transparent conductive layer to the second opening, and the opening width of the second opening gradually increases in a direction from the first opening to the metal reflective layer.

3. The LED as claimed in claim 1, wherein an inclination of a sidewall of the first opening is smaller than an inclination of a sidewall of the second opening.

4. The LED as claimed in claim 1, wherein a sidewall of the second opening is arc-shaped.

5. The LED as claimed in claim 1, wherein an opening width of a lower opening of the second opening is more than twice of an opening width of a lower opening of the first opening.

6. The LED as claimed in claim 1, wherein the insulating structure comprises:
a first insulating layer, wherein the first insulating layer is disposed on a side of the transparent conductive layer facing away from the epitaxial structure, and the first opening is defined in a part of the first insulating layer close to the transparent conductive layer; and
an insulating reflective layer, wherein the insulating reflective layer is disposed on a side of the first insulating layer facing away from the transparent conductive layer; and the second opening is defined in the insulating reflective layer, and extends from the insulating reflective layer to another part of the first insulating layer and is in contact with an edge of the first opening.

7. The LED as claimed in claim 6, wherein a sidewall of the second opening comprises an entire sidewall of the insulating reflective layer and a part of a sidewall of the first insulating layer.

8. The LED as claimed in claim 6, wherein a thickness of the insulating reflective layer is greater than a thickness of the first insulating layer.

9. The LED as claimed in claim 6, wherein the insulating reflective layer is a distributed Bragg reflector (DBR) reflective layer.

10. The LED as claimed in claim 9, wherein the DBR reflective layer comprises a plurality of layer pairs arranged in a stacked manner along a direction from the first insulating layer to the insulating reflective layer, each layer pair of the plurality of layer pairs consists of a first material layer and a second material layer, and a refractive index of the first material layer is greater than a refractive index of the second material layer.

11. The LED as claimed in claim 10, wherein the first material layer is a titanium oxide layer, and the second material layer is a silicon oxide layer.

12. The LED as claimed in claim 10, wherein a thickness of the second material layer of at least one layer pair in half of the layer pairs close to the first insulating layer of the DBR reflecting layer is greater than a thickness of the second material layer of each layer pair in the other half of the layer pairs.

13. The LED as claimed in claim 6, wherein the first insulating layer is a silicon dioxide layer.

14. The LED as claimed in claim 1, wherein the opening width of the first opening is in a range from 1 μm to 5 μm, and the opening width of the second opening is in a range from 2 μm to 10 μm.

15. The LED as claimed in claim 1, wherein the metal reflective layer is a silver layer.

16. The LED as claimed in claim 1, wherein the epitaxial structure is defined with a through hole etched from the second semiconductor layer to the first semiconductor layer, and a part of the first semiconductor layer is exposed from a bottom of the through hole.

17. The LED as claimed in claim 16, wherein a second insulating layer is disposed on a side of the metal reflective layer facing away from the insulating structure, a third opening is defined in the second insulating layer at the through hole, the opening width of the first opening is smaller than an opening width of the third opening, and the opening width of the third opening is smaller than the opening width of the second opening.

18. The LED as claimed in claim 16, further comprising:
a first electrode, wherein the first electrode is disposed on a side of the metal reflective layer facing away from the insulating structure and is electrically connected with the metal reflective layer; and
a second electrode, wherein the second electrode is disposed on the side of the metal reflective layer facing away from the insulating structure, the second electrode is insulated from and connected with the metal reflective layer, and the second electrode is electrically connected with the part of the first semiconductor layer exposed at the bottom of the through hole.

19. The LED as claimed in claim 18, further comprising:
a first electrode contact layer, disposed between the metal reflection layer and the first electrode;
a second insulating layer, disposed on a side of the metal reflective layer facing away from the insulating structure; and
a second electrode contact layer, disposed between the second insulating layer and the second electrode.

20. A light emitting device, comprising:
a package substrate; and
at least one LED, disposed on a surface of the package substrate, the package substrate is electrically connected to the at least one LED, and each of the at least one LED is the LED as claimed in claim 1.
